(19) United States
(12) Patent Application Publication
(10) Pub. No.: US 2024/0334793 A1
(43) Pub. Date: Oct. 3, 2024

(54) DISPLAY DEVICE AND METHOD OF MANUFACTURING THE SAME

(71) Applicant: Samsung Display Co., LTD., Yongin-si (KR)

(72) Inventors: BYUNGHOON KANG, Yongin-si (KR); SANGHOON KIM, Yongin-si (KR); SUNGHOON KIM, Yongin-si (KR); JINGYU SIM, Yongin-si (KR); HYUNJI LEE, Yongin-si (KR); TAEHYEOG JUNG, Yongin-si (KR); SEONGJIN HWANG, Yongin-si (KR)

(21) Appl. No.: 18/422,885

(22) Filed: Jan. 25, 2024

(30) Foreign Application Priority Data
Mar. 27, 2023 (KR) 10-2023-0039800

(51) Int. Cl. H10K 59/80; H10K 59/12; H10K 59/126; H10K 102/00

(52) U.S. Cl. CPC H10K 59/879; H10K 59/1201; H10K 59/126; H10K 2102/311; H10K 2102/351

(57) ABSTRACT

A display device includes a display module displaying an image and a window module disposed on the display module, where the window module is foldable. The window module includes a window layer including a base layer with a recess pattern and a filler filled in the recess pattern, and a coating layer disposed on the window layer and contacting an upper surface of the base layer.

This application claims priority to Korean Patent Application No. 10-2023-0039800, filed on Mar. 27, 2023, and all the benefits accruing therefrom under 35 U.S.C. § 119, the content of which in its entirety is herein incorporated by reference.

### BACKGROUND

### 1. Field

The disclosure relates to a display device and a method of manufacturing the display device. More specifically, the disclosure relates to a display device having a flexible characteristic and a manufacturing method of the display device.

### 2. Description of the Related Art

A flat panel display device (e.g., an organic light emitting display device) may have various desired characteristics of being light in weight and thin in thickness. Recently, development of flexible display devices having flexible characteristics is increasing. For example, the flexible display device includes a curved display device, a bended display device, a foldable display device, a rollable display device, a stretchable display device, and the like. The flexible display device may include a display module and a window disposed on the display module. In the flexible display device, grooves may be formed in the window so that the window may be smoothly folded.

### SUMMARY

Embodiments provide a display device having improved durability and flexible characteristics.

Embodiments provide a method for manufacturing the display device.

A display device according to an embodiment includes a display module which displays an image and a window module disposed on the display module, where the window module is foldable, and the window module includes a window layer including a base layer with a recess pattern and a filler filled in the recess pattern, and a coating layer disposed on the window layer and contacting an upper surface of the base layer.

In an embodiment, a modulus of the coating layer may be about 2 times to about 20 times a modulus of the window layer.

In an embodiment, the modulus of the window layer may be in a range of about 5 megapascals (Mpa) to about 100 Mpa, and the modulus of the coating layer may be in a range of about 10 Mpa to about 2000 Mpa.

In an embodiment, a thickness of the window layer may be in a range of about 100 micrometers (μm) to about 200 μm, and a thickness of the coating layer may be in a range of about 10 μm to about 50 μm.

In an embodiment, the recess pattern may be an opening pattern defined through the base layer.

In an embodiment, the recess pattern may be a trench pattern which is depressed into the base layer from a lower surface opposite to the upper surface of the base layer.

In an embodiment, the window module may further include a light blocking member disposed on the base layer, and the coating layer may contact the light blocking member and covers the light blocking member.

In an embodiment, the display device may further include a light blocking member disposed between the display module and the window module, and an adhesive layer disposed between the display module and the window module and contacting the light blocking member.

In an embodiment, the coating layer may cover the upper surface of the base layer.

In an embodiment, the coating layer may cover the upper surface of the base layer and a side surface of the base layer.

A method of manufacturing a display device according to an embodiment includes forming a display module which displays an image, forming a window module, and bonding the display module and the window module to each other, and the forming the window module may include radiating a laser to a base layer, forming an opening pattern through the base layer by etching the base layer by reacting an etchant with an area irradiated with the laser, forming an adhesive layer on the lower surface of the base layer, forming a window layer including the base layer and a filler by filling the opening pattern with the filler, and forming a coating layer on an upper surface opposite to the lower surface of the base layer.

In an embodiment, the coating layer may be formed by at least one process selected from inkjet printing, roll laminating, spray coating, spin coating, roll coating, slot coating, dip coating, bar coating, gravure coating, micro gravure coating, and wire coating.

In an embodiment, the window layer may have a thickness in a range of about 100 μm to about 200 μm, the coating layer may have a thickness in a range of about 10 μm to about 50 μm, and a modulus of the coating layer may be in a range of about 2 times to about 20 times a modulus of the window layer.

In an embodiment, the forming of window module may include forming a light blocking member on the base layer after the forming the window layer and before the forming the coating layer, and the coating layer may be formed to contact the light blocking member and cover the light blocking member.

In an embodiment, the forming the window module may further include forming a light blocking member under the base layer, and the adhesive layer may be formed to contact the light blocking member.

A method of manufacturing a display device according to an embodiment includes forming a display module which displays an image, forming a window module, and bonding the display module and the window module to each other, and the forming the window module may include radiating a laser to a base layer, forming a coating layer to contact the base layer on an upper surface of the base layer, forming a trench pattern which is depressed into the base layer from a lower surface opposite to the upper surface of the base layer by etching the base layer by reacting an etchant with an area irradiated with the laser, forming a window layer including the base layer and a filler by filling the trench pattern with the filler, and forming an adhesive layer on the lower surface of the base layer.

In an embodiment, the coating layer may be formed by at least one process selected from inkjet printing, roll laminating, spray coating, spin coating, roll coating, slot coating, dip coating, bar coating, gravure coating, micro gravure coating, and wire coating.

In an embodiment, the window layer may have a thickness of about 100 μm to about 200 μm, the coating layer may have a thickness of about 10 μm to about 50 μm, and a modulus of the coating layer may be about 2 times to about 20 times a modulus of the window layer.

In an embodiment, the forming the window module may include forming a light blocking member on the base layer before the forming the coating layer, and the coating layer may be formed to contact the light blocking member and cover the light blocking member.

In an embodiment, the forming the window module may include forming a light blocking member on a lower surface of the window layer opposite to an upper surface of the window layer on which the coating layer is formed, and the adhesive layer may be formed to contact the light blocking member.

In the display device according to embodiments, the display device may include the display module and the window module disposed on the display module and capable of being folded. Also, the window module may include the window layer and the coating layer disposed on the window layer. In such embodiments, the window layer may include the base layer and the filler filled in the recess pattern defined in the base layer, and the coating layer may contact the upper surface of the base layer. In such embodiments, the coating layer may be directly formed on or disposed directly on the upper surface of the base layer.

In such embodiments, as the window module includes the coating layer contacting the upper surface of the base layer, the window layer included in the window module may have a low modulus and may be smoothly folded. In an embodiment, for example, as the window module includes the coating layer, the window layer included in the window module may have a modulus of about 100 Mpa or less. Accordingly, the window module may be smoothly folded, and a durability of the window module may be improved. Accordingly, structural reliability of the display device may be improved.

It is to be understood that both the foregoing general description and the following detailed description are exemplary and explanatory and are intended to provide further explanation of the invention as claimed.

### BRIEF DESCRIPTION OF THE DRAWINGS

Illustrative, non-limiting embodiments will be more clearly understood from the following detailed description taken in conjunction with the accompanying drawings.

FIG. 1 is a plan view illustrating a display device according to an embodiment.

FIG. 2 is a cross-sectional view taken along line I-T of FIG. 1 illustrating an embodiment.

FIG. 3 is a cross-sectional view illustrating an embodiment of a display module included in the display device of FIG. 2.

FIGS. 4 to 10 are cross-sectional views illustrating an embodiment of a manufacturing method of the display device of FIG. 2.

FIG. 11 is a cross-sectional view taken along line I-T of FIG. 1 illustrating an alternative embodiment.

FIGS. 12 and 13 are cross-sectional views illustrating an embodiment of a manufacturing method of the display device of FIG. 11.

FIG. 14 is a cross-sectional view taken along line I-T of FIG. 1 illustrating an alternative embodiment.

FIGS. 15 to 17 are cross-sectional views illustrating an embodiment of a manufacturing method of the display device of FIG. 14.

FIG. 18 is a plan view illustrating a display device according to an embodiment.

FIG. 19 is a cross-sectional view taken along line II-II of FIG. 18 illustrating an embodiment.

FIGS. 20 to 26 are cross-sectional views illustrating an embodiment of a manufacturing method of the display device of FIG. 19.

FIG. 27 is a cross-sectional view taken along line II-II of FIG. 18 illustrating an alternative embodiment.

FIGS. 28 to 30 are cross-sectional views illustrating an embodiment of a manufacturing method of the display device of FIG. 27.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

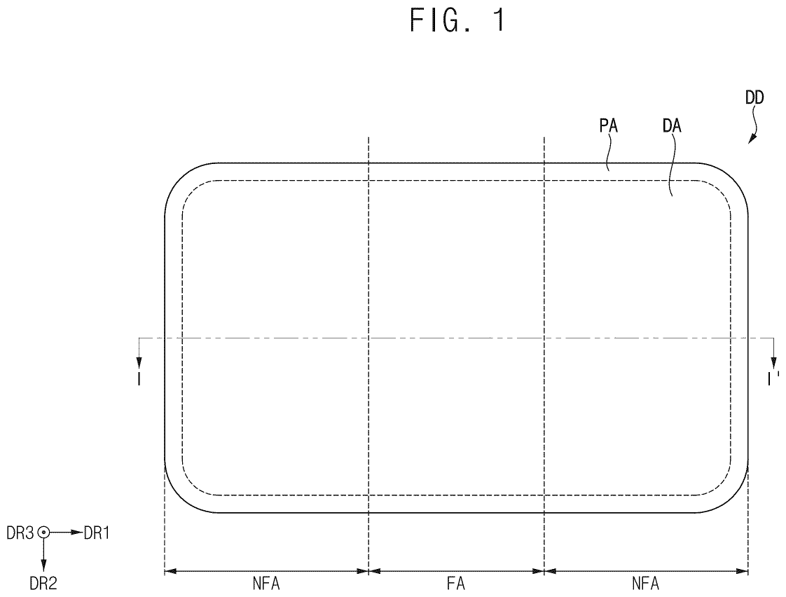

FIG. 1 is a plan view illustrating a display device according to an embodiment.

Referring to FIG. 1, an embodiment of a display device DD may be divided into a plurality of areas. In an embodiment, for example, the display device DD may be divided into a display area DA and a peripheral area PA. The display area DA may display an image, and the peripheral area PA may be positioned around the display area DA. In an embodiment, for example, the peripheral area PA may surround the display area DA.

In an embodiment, the display device DD may have a rectangular shape with rounded corners in a plan view. However, the invention is not necessarily limited thereto, and the display device DD may have various shapes in a plan view. In such an embodiment, a plane may be defined from a first direction DR1 and a second direction DR2 perpendicular to the first direction DR1. A third direction DR3 may be orthogonal to the plane. That is, the third direction DR3 may be a direction normal to the plane or a thickness direction of the display device DD. The display area DA may display the image in the third direction DR3. Here, the phrase “in a plan view” means “when viewed in the third direction DR3”.

The display device DD may include a plurality of pixels disposed in the display area DA. In an embodiment, for example, the pixels may be arranged in a matrix form along the first and second directions DR1 and DR2.

A driver may be disposed in the peripheral area PA. The driver may provide signals and/or voltages to the pixels. In an embodiment, for example, the driver may include a data driver and a gate driver.

In an embodiment, the display device DD may include a folding area FA and a non-folding area NFA adjacent to the folding area FA. In an embodiment, for example, as shown in FIG. 1, the display device DD may include the folding area FA overlapping a central portion of the display device DD and the non-folding area NFA adjacent to a left side and a right side of the folding area FA. Accordingly, the display device DD may be folded in the folding area FA.

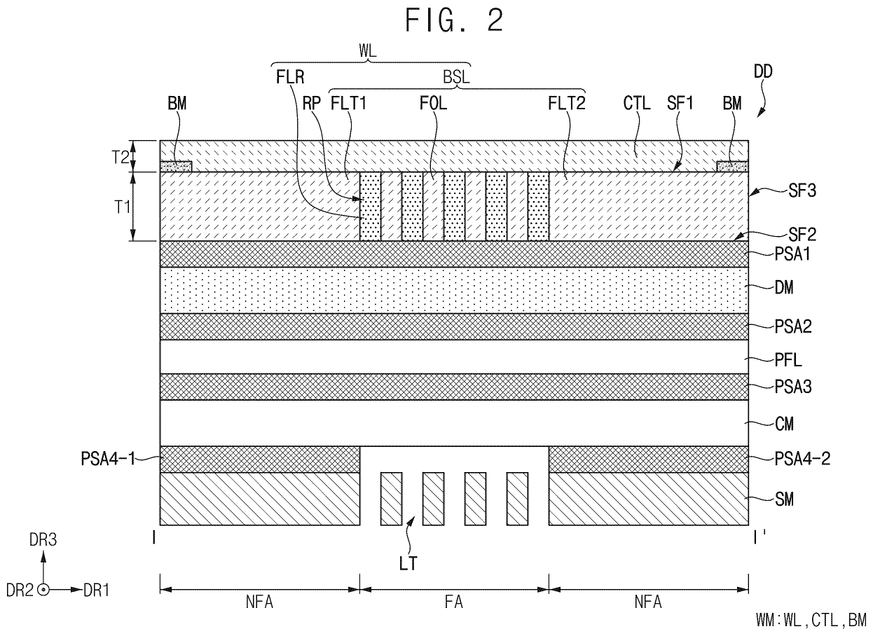

FIG. 2 is a cross-sectional view taken along line I-I of FIG. 1 illustrating an embodiment.

Referring to FIGS. 1 and 2, an embodiment of the display device DD may include a support module SM, a buffer member CM, a protective film PFL, a display module DM, a window module WM, and adhesive layers PSA1, PSA2, PSA3, PSA4-1, and PAS4-2.

The support module SM may be disposed under the display module DM. The support module SM may include or be formed of metal and support the display module DM. In an embodiment, for example, the support module SM may include at least one of invar, which is an alloy of nickel (Ni) and iron (Fe), stainless steel (SUS), titanium (Ti), and copper (Cu). These may be used alone or in combination with each other.

A lattice LT may be defined or formed in the support module SM therethrough. In an embodiment, the lattice LT may overlap the folding area FA. As the lattice LT is defined in the support module SM, the support module SM may be smoothly folded in the folding area FA.

The buffer member CM may be disposed between the support module SM and the display module DM. The buffer member CM may buffer an external shock that may be applied to the display module DM and protect the display module DM. In such an embodiment, the buffer member CM may include a material capable of buffering by containing air, such as a cushion or a sponge. Also, to facilitate folding and unfolding of the display module DM, the buffer member CM may include a flexible material. In an embodiment, for example, the buffering member CM may include or be formed of acrylic resin, polyurethane, thermoplastic polyurethane, latex, polyurethane foam, or polystyrene foam, or the like. These may be used alone or in combination with each other.

The protective film PFL may be disposed between the buffer member CM and the display module DM. The protective film PFL may prevent penetration of moisture and oxygen from the outside and may absorb external impact. To implement a flexible display device, the display module DM may include a plastic substrate that is flexible, and the protective film PFL may support the plastic substrate.

In an embodiment, for example, the protective film PFL may be a plastic film. For example, the protective film PFL may include polyethersulfone (PS), polyacrylate (PAR), polyetherimide (PEI), polyethylenenaphthalate (PEN), polyphenylene sulfide (PPS), polyarylate (PA), polycarbonate (PC), poly arylene ethersulfone, polyethylene terephthalate (PET), polyimide (PI), or the like. These may be used alone or in combination with each other.

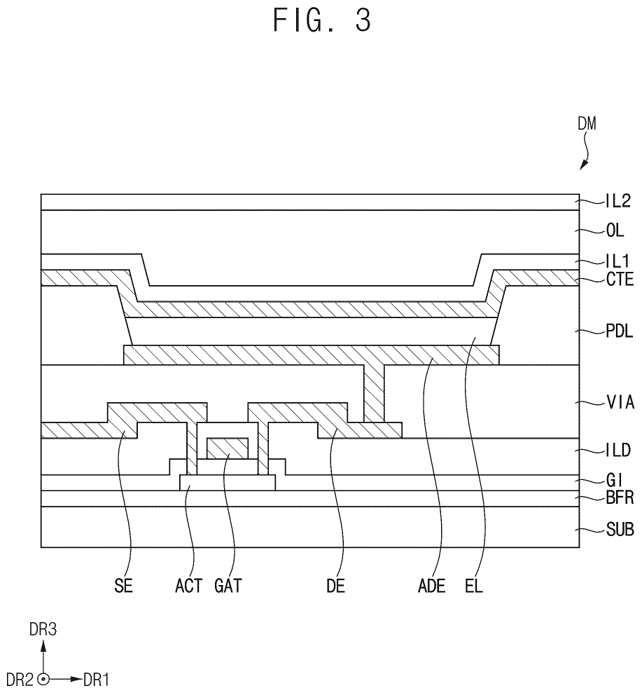

The display module DM may be disposed between the protective film PFL and the window module WM. The image may be displayed in the display module DM. A detailed structure of the display module DM will be described later with reference to FIG. 3.

The window module WM may be disposed on the display module DM. The window module WM may buffer external impact that may be applied to the display module DM and protect the display module DM.

In an embodiment, the window module WM may include a window layer WL and a coating layer CTL. The window layer WL may include a base layer BSL and a filler FLR.

The base layer BSL may include a folding portion FOL, a first flat portion FLT1, and a second flat portion FLT2. The folding portion FOL may overlap the folding area FA, and the first flat portion FLT1 and the second flat portion FLT2 may overlap the non-folding area NFA. In an embodiment, for example, the first flat portion FLT1 may be adjacent to a left side of the folding portion FOL, and the second flat portion FLT2 may be adjacent to a right side of the folding portion FOL.

In an embodiment, the base layer BSL may include a rigid material. In an embodiment, for example, the base layer BSL may be glass or ultra-thin glass (UTG). Examples of materials that can be used as the glass may include soda lime glass, alkali alumino silicate glass, borosilicate glass, lithium alumina silicate glass, or the like. These may be used alone or in combination with each other.

A recess pattern RP may be defined in the folding portion FOL. In an embodiment, the recess pattern RP may be an opening pattern defined or formed through the base layer BSL. That is, the recess pattern RP may extend from a first surface SF1 (or upper surface) of the base layer BSL to a second surface SF2 (or lower surface) of the base layer BSL. However, the invention is not necessarily limited thereto.

In an embodiment, the filler FLR may be filled in the recess pattern RP. The filler FLR may include a soft material. In an embodiment, for example, the filler FLR may be a resin. In an embodiment, for example, the filler FLR may be a resin having a same refractive index as a refractive index of the base layer BSL. Accordingly, refractive indices of the base layer BSL and the filler FLR may be the same as each other.

As the base layer BSL includes the rigid material, a hardness of the base layer BSL may increase. In addition, as the recess pattern RP is formed in the base layer BSL and the filler FLR is in the recess pattern RP, the folding portion FOL may be smoothly folded. That is, the window layer WL may be smoothly folded. Also, since the refractive index of the filler FLR is same as the refractive index of the base layer BSL, display quality in the folding portion FOL may be improved.

In an embodiment, a modulus of the window layer WL may be about 100 megapascals (Mpa) or less. Specifically, the modulus of the window layer WL may be in a range of about 5 Mpa to about 100 Mpa, e.g., in a range of about 5 Mpa to about 50 Mpa, or in a range of about 5 Mpa to about 10 Mpa. In such an embodiment where the modulus of the window layer WL satisfies the above range, the window layer WL may have better hardness, and the window layer WL may be folded more smoothly.

In an embodiment, a first thickness T1 of the window layer WL may be in a range of about 100 micrometers (μm) to about 200 μm, e.g., in a range of about 100 μm to about 150 μm. Here, the first thickness T1 of the window layer WL may be a straight-line distance from the second surface SF2 of the base layer BSL to the first surface SF1 of the base layer BSL. In such an embodiment where the first thickness T1 of the window layer WL satisfies the above range, the window layer WL may have better hardness, and the window layer WL may be folded more smoothly.

The coating layer CTL may be disposed on the window layer WL. That is, the coating layer CTL may be disposed on the first surface SF1 of the base layer BSL. Specifically, the coating layer CTL may contact the first surface SF1 of the base layer BSL. In a range of example, a separate adhesive layer may not be interposed between the coating layer CTL and the window layer WL. In other words, the coating layer CTL may be directly formed on the first surface SF1 of the base layer BSL.

The coating layer CTL may cover the first surface SF1 of the base layer BSL. In such an embodiment, the coating layer CTL may cover the upper surface of the window layer WL. In an embodiment, the coating layer CTL may expose a third surface SF3 (or side surface) of the base layer BSL. However, the invention is not necessarily limited thereto.

In an embodiment, the coating layer CTL may include an organic material. For example, the coating layer CTL may include an epoxy-based resin, an acrylic-based resin, an imide-based resin, or the like. The coating layer CTL may improve an impact resistance of the window layer WL.

As the window module WM includes the coating layer CTL contacting the first surface SF1 of the base layer BSL, the window module WM may include the window layer WL having a low modulus, and may be folded smoothly. In a range of example, as the window module WM includes the coating layer CTL, the window module WM may include the window layer WL having a modulus of about 100 Mpa or less. Accordingly, the window module WM may be smoothly folded, and a durability of the window module WM may be improved.

In an embodiment, a modulus of the coating layer CTL may be in a range of about 2 times to about 20 times the modulus of the window layer WL. In an embodiment, the modulus of the coating layer CTL may be about 2000 Mpa or less. In an embodiment, for example, the modulus of the coating layer CTL may be in a range of about 10 Mpa to about 2000 Mpa, e.g., in a range of about 10 Mpa to about 500 Mpa, or in a range of about 10 Mpa to about 100 Mpa. In such an embodiment where the modulus of the window layer WL and the modulus of the coating layer CTL satisfy the above ranges, the window module WM including the window layer WL and the coating layer CTL may be more smoothly folded, and peeling of the coating layer CTL may be effectively prevented or substantially reduced.

In an embodiment, a second thickness T2 of the coating layer CTL may in a range of be about 10 μm to about 50 μm, e.g., in a range of about 30 μm to about 50 μm. Here, the second thickness T2 of the coating layer CTL may be a straight-line distance from the first surface SF1 of the base layer BSL to an upper surface of the coating layer CTL. In such an embodiment where the second thickness T2 of the coating layer CTL satisfies the above range, damage to the window layer WL when the window module WM is folded may be prevented or reduced, and peeling of the coating layer CTL may be prevented or reduced. Accordingly, durability of the window module WM may be improved.

In an embodiment, the window module WM may further include a light blocking member BM.

The light blocking member BM may be disposed on the base layer BSL. That is, the light blocking member BM may be disposed on the first surface SF1 of the base layer BSL. In an embodiment, for example, the light blocking member BM may be disposed along an outer edge of the base layer BSL. That is, the light blocking member BM may have a closed loop shape in a plan view. The light blocking member BM may be covered by the coating layer CTL. That is, the light blocking member BM may contact the coating layer CTL.

In an embodiment, the light blocking member BM may absorb light. Accordingly, the light blocking member BM may reduce an external light reflectance of the display device DD. Also, the light blocking member BM may prevent or reduce a light leakage phenomenon. Examples of materials that can be used as the light blocking member BM may include chromium (Cr), chromium oxide (CrOx), chromium nitride (CrNx), carbon black, a black pigment mixture, a black dye mixture, or the like. These may be used alone or in combination with each other.

A first adhesive layer PSA1 may be disposed between the display module DM and the window module WM. The first adhesive layer PSA1 may adhere the window module WM to the display module DM. In an embodiment, the first adhesive layer PSA1 may include pressure sensitive adhesive (PSA), optically clear adhesive (OCA), optically clear resin (OCR), or the like. These may be used alone or in combination with each other.

A second adhesive layer PSA2 may be disposed between the protective film PFL and the display module DM. The second adhesive layer PSA2 may adhere the protective film PFL to the display module DM. The second adhesive layer PSA2 may include pressure sensitive adhesive (PSA), optically clear adhesive (OCA), optically clear resin (OCR), or the like. These may be used alone or in combination with each other.

A third adhesive layer PSA3 may be disposed between the buffer member CM and the protective film PFL. The third adhesive layer PSA3 may adhere the buffer member CM to the protective film PFL. The third adhesive layer PSA3 may include pressure sensitive adhesive (PSA), optically clear adhesive (OCA), optically clear resin (OCR), or the like. These may be used alone or in combination with each other.

A fourth adhesive layer may be disposed between the support module SM and the buffer member CM. The fourth adhesive layer may adhere the support module SM to the buffer member CM. In an embodiment, the fourth adhesive layer may include a first sub adhesive layer PSA4-1 and a second sub adhesive layer PSA4-2. The first sub adhesive layer PSA4-1 and the second sub adhesive layer PSA4-2 may be spaced apart from each other with the folding area FA therebetween. In an embodiment, for example, the first sub adhesive layer PSA4-1 may be disposed in the non-folding area NFA adjacent to the left side of the folding area FA, and the second sub adhesive layer PSA4-2 may be disposed in the non-folding area NFA adjacent to the right side of the folding area FA.

The first sub adhesive layer PSA4-1 and the second sub adhesive layer PSA4-2 may include pressure sensitive adhesive (PSA), optically clear adhesive (OCA), optically clear resin (OCR), or the like. These may be used alone or in combination with each other.

FIG. 3 is a cross-sectional view illustrating an embodiment of a display module included in the display device of FIG. 2.

Referring to FIG. 3, an embodiment of the display module DM may include a substrate SUB, a buffer layer BFR, an active pattern ACT, a gate insulating layer GI, a gate electrode GAT, an interlayer insulating layer ILD, a source electrode SE, a drain electrode DE, a via insulating layer VIA, a first electrode ADE, a pixel defining layer PDL, a light emitting layer EL, a second electrode CTE, a first inorganic layer IL1, an organic layer OL, and a second inorganic layer IL2.

The substrate SUB may include a transparent or opaque material. In an embodiment, examples of materials that can be used as the substrate SUB may include glass, quartz, plastic, or the like. These may be used alone or in combination with each other. In addition, the substrate SUB may be formed of or defined by a single layer or multiple layers in combination with each other.

The buffer layer BFR may be disposed on the substrate SUB. The buffer layer BFR may prevent diffusion of metal atoms or impurities from the substrate SUB into the active pattern ACT. Also, the buffer layer BFR may control a heat supply rate during a crystallization process for forming the active pattern ACT.

The active pattern ACT may be disposed on the buffer layer BFR. The active pattern ACT may include or be formed of a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may include InGaZnO (IGZO) and InSnZnO (ITZO). These may be used alone or in combination with each other.

The gate insulating layer GI may be disposed on the active pattern ACT and may cover the active pattern ACT. In an embodiment, the gate insulating layer GI may include or be formed of an insulating material. Examples of an insulating material that can be used as the gate insulating layer GI may include silicon oxide, silicon nitride, silicon oxynitride, or the like. These may be used alone or in combination with each other.

The gate electrode GAT may be disposed on the gate insulating layer GI and may overlap the active pattern ACT. In an embodiment, the gate electrode GAT may include or be formed of metal, alloy, conductive metal oxide, transparent conductive material, or the like. Examples of materials that can be used as the gate electrode GAT may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), or the like. These may be used alone or in combination with each other. In addition, the gate electrode GAT may be formed of or defined by a single layer or multiple layers in combination with each other.

The interlayer insulating layer ILD may be disposed on the gate electrode GAT and may cover the gate electrode GAT. In an embodiment, the interlayer insulating layer ILD may include or be formed of an insulating material. Examples of insulating materials that can be used as the interlayer insulating layer ILD may include silicon oxide, silicon nitride, silicon oxynitride, or the like. These may be used alone or in combination with each other. In addition, the Interlayer insulating layer ILD may be formed of or defined by a single layer or multiple layers in combination with each other.

The source electrode SE and the drain electrode DE may be disposed on the interlayer insulating layer ILD. Each of the source electrode SE and the drain electrode DE may contact the active pattern ACT. In an embodiment, the source electrode SE and the drain electrode DE may include or be formed of a metal, an alloy, a conductive metal oxide, a transparent conductive material, or the like.

The via insulating layer VIA may be disposed on the source electrode SE and the drain electrode DE, and may cover the source electrode SE and the drain electrode DE. The via insulating layer VIA may include or be formed of an insulating material. Examples of insulating materials that can be used as the via insulating layer VIA may include photoresist, polyacrylic resin, polyimide resin, acrylic resin, or the like. These may be used alone or in combination with each other.

The first electrode ADE may be disposed on the via insulating layer VIA. In an embodiment, the first electrode ADE may be electrically connected to the drain electrode DE. The first electrode ADE may include or be formed of a metal, an alloy, a conductive metal oxide, a transparent conductive material, or the like.

The pixel defining layer PDL may be disposed on the via insulating layer VIA, and an opening exposing the first electrode ADE may be defined or formed in the pixel defining layer PDL. The pixel defining layer PDL may include or be formed of an insulating material. Examples of insulating materials that can be used as the pixel definition layer PDL may include photoresist, polyacrylic resin, polyimide resin, acrylic resin, or the like. These may be used alone or in combination with each other.

The light emitting layer EL may be disposed on the first electrode ADE. In an embodiment, for example, the light emitting layer EL may be disposed in the opening. The light emitting layer EL may generate light based on a potential difference between the first electrode ADE and the second electrode CTE.

The second electrode CTE may be disposed on the light emitting layer EL. The second electrode CTE may be implemented as a plate electrode and may include or be formed of a metal, an alloy, a conductive metal oxide, a transparent conductive material, or the like.

The first inorganic layer IL1 may be disposed on the second electrode CTE and may include or be formed of an inorganic material. The organic layer OL may be disposed on the first inorganic layer IL1 and may include or be formed of an organic material. The second inorganic layer IL2 may be disposed on the organic layer OL and may include or be formed of an inorganic material. The first inorganic layer IL1, the organic layer OL, and the second inorganic layer IL2 may prevent foreign matter from penetrating into the light emitting layer EL.

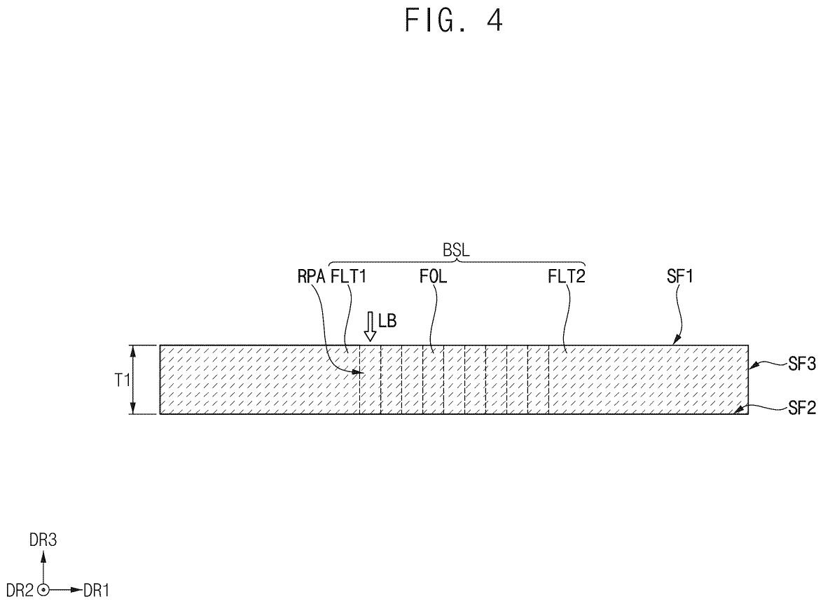

FIGS. 4 to 10 are cross-sectional views illustrating an embodiment of a manufacturing method of the display device of FIG. 2.

The display device DD may include the window module WM and the display module DM, and an embodiment of a manufacturing method of the display device DD may include forming the display module DM, forming the window module WM, and bonding the display module DM and the window module WM to each other. Hereinafter, a process of forming the window module WM of FIG. 2 and a process of bonding the window module WM and display module DM of FIG. 2 will be described in detail with reference to FIGS. 4 to 10.

Referring to FIG. 4, the base layer BSL may be prepared. The base layer BSL may include the first surface SF1, the second surface SF2, and the third surface SF3. The first surface SF1 and the second surface SF2 may be opposite to each other. The third surface SF3 may connect the first surface SF1 and the second surface SF2 and may be a side surface of the base layer BSL.

In an embodiment, the base layer BSL may have the first thickness T1 in a range of about 100 μm to about 200 μm. In an embodiment, for example, the base layer BSL may have the first thickness T1 of about 100 μm to about 150 μm.

A laser LB may be radiated to a recess pattern area RPA of the base layer BSL. In an embodiment, the recess pattern area RPA may be an area where the recess pattern RP is to be formed. The laser LB may travel in the first direction DR1 and may be radiated to the first surface SF1. In an embodiment, the laser LB may be selectively radiated to a portion of the first surface SF1 corresponding to the recess pattern area RPA. As the laser LB is radiated onto the recess pattern area RPA, the recess pattern area RPA may have a different etching selectivity than an area not irradiated with the laser LB.

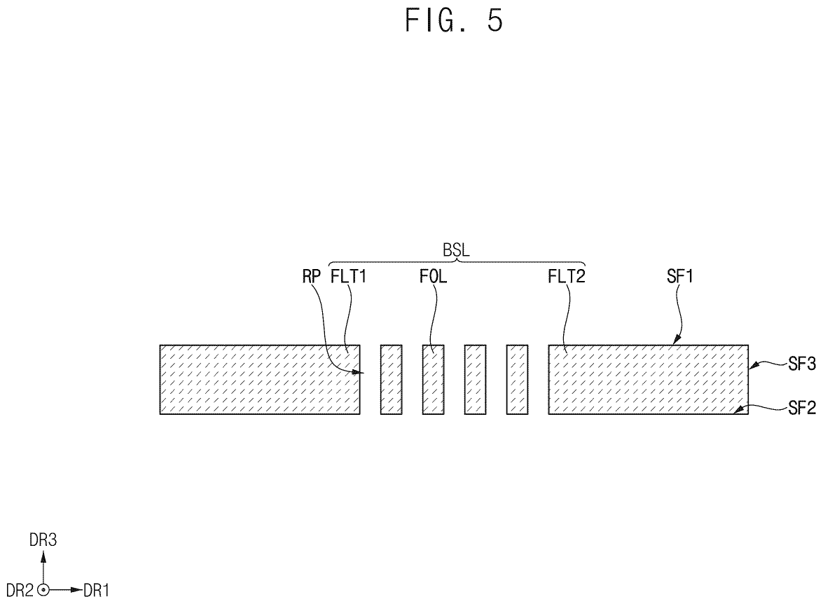

Further referring to FIG. 5, the base layer BSL may be etched in a way such that the recess pattern RP may be formed. That is, the base layer BSL may react with an etchant. In this case, various processes for bringing the base layer BSL into contact with the etchant may be used. In an embodiment, for example, the base layer BSL may be immersed in the etchant or the etchant may be sprayed on the base layer BSL.

In such an embodiment, as described above, the recess pattern area RPA may have a different etching selectivity than the area not irradiated with the laser LB. Accordingly, the recess pattern area RPA may react with the etchant, and the base layer BSL corresponding to the recess pattern area RPA may be etched. Thus, the recess pattern RP may be formed. In an embodiment, the recess pattern RP may be an opening pattern formed through the base layer BSL.

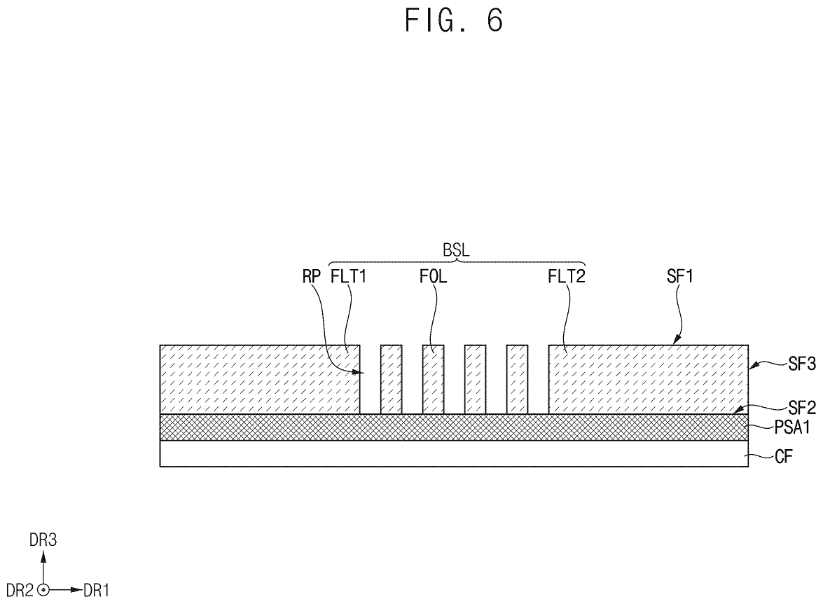

Further referring to FIG. 6, the first adhesive layer PSA1 may be formed on the second surface SF2 of the base layer BSL. In an embodiment, a carrier film CF may be positioned under the first adhesive layer PSA1. As the first adhesive layer PSA1 is formed on the second surface SF2 of the base layer BSL, an accommodation space may be defined in the folding portion FOL.

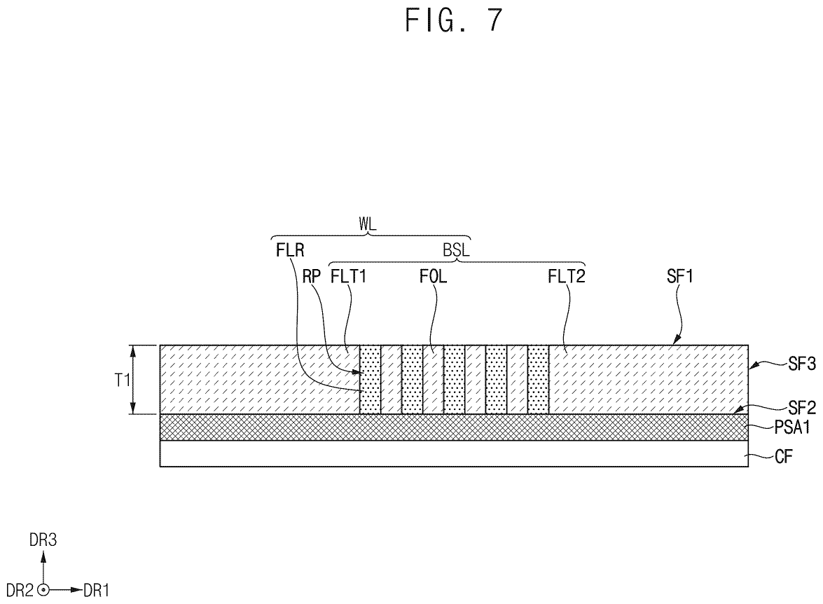

Further referring to FIG. 7, the filler FLR may be filled in the recess pattern RP. That is, the filling material FLR may be filled in the accommodation space. Accordingly, the window layer WL including the base layer BSL and the filler FLR may be formed.

As described above, the base layer BSL may have the first thickness T1 in a range of about 100 μm to about 200 μm. In an embodiment, for example, the base layer BSL may have the first thickness T1 in a range of about 100 μm to about 150 μm. Accordingly, the window layer WL may be formed to have the first thickness T1 in a range of about 100 μm to about 200 μm, e.g., in a range of about 100 μm to about 150 μm.

The filler FLR may be filled in various ways. In an embodiment, the filler FLR may be filled through an inkjet process. In an alternative embodiment, the filler FLR may be filled through a spray coating process. In another alternative embodiment, the filler FLR may be filled through a roll laminating process. However, a process of filling the filler FLR is not limited thereto.

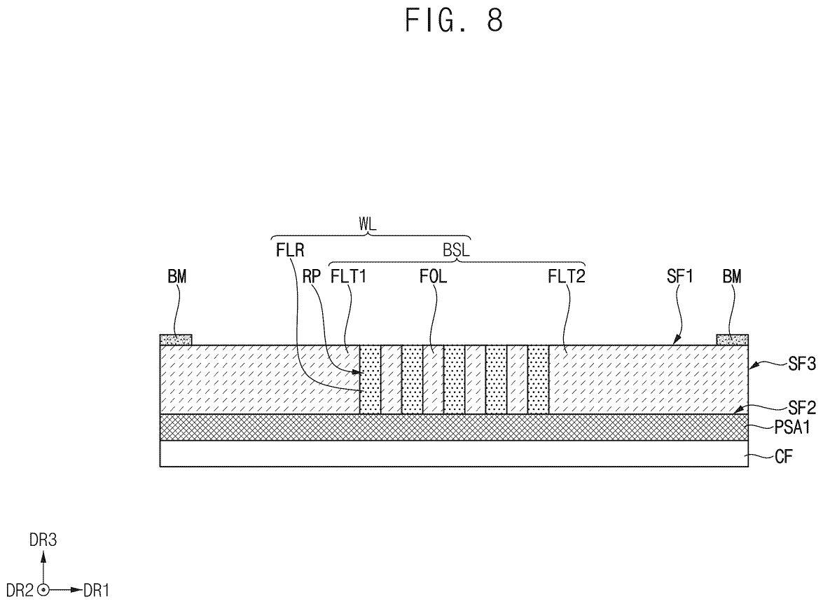

Further referring to FIG. 8, the light blocking member BM may be formed on the base layer BSL. The light blocking member BM may be formed along the outer edge of the base layer BSL. That is, the light blocking member BM may be formed in a closed loop shape in a plan view.

The light blocking member BM may be formed in various ways. In an embodiment, the light blocking member BM may be formed through an inkjet printing process. In an alternative embodiment, the light blocking member BM may be formed through a screen-printing process. However, a process of forming the light blocking member BM is not limited thereto.

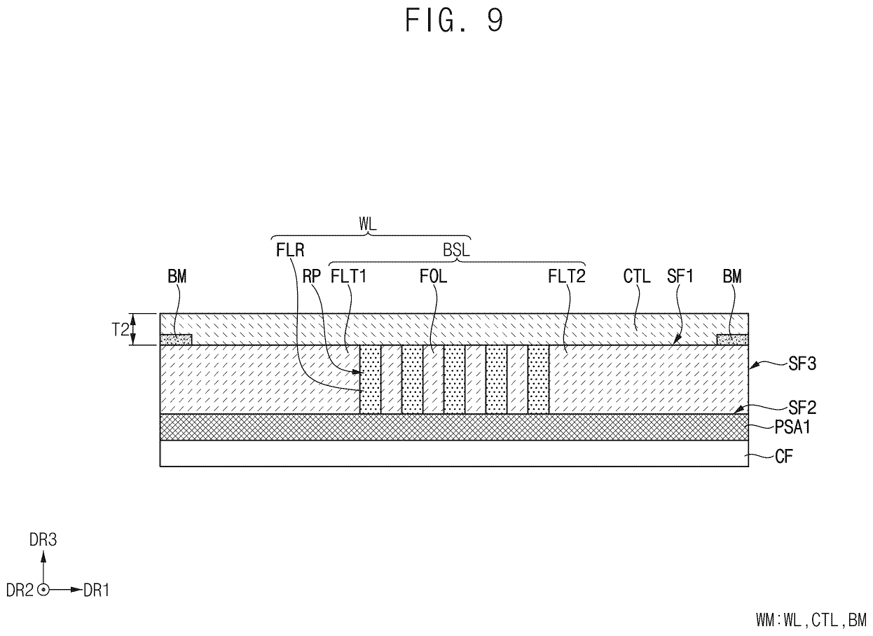

Further referring to FIG. 9, the coating layer CTL may be formed on the first surface SF1 of the base layer BSL. Accordingly, the window module WM including the window layer WL, the light blocking member BM, and the coating layer CTL may be formed.

In an embodiment, the coating layer CTL may be directly formed on the first surface SF1 of the base layer BSL. That is, the coating layer CTL may be formed to contact the first surface SF1 of the base layer BSL. In an embodiment, for example, the coating layer CTL may be formed to cover the first surface SF1 of the base layer BSL. In such an embodiment, the coating layer CTL may be formed to cover the upper surface of the window layer WL. In an embodiment, the coating layer CTL may be formed to expose the third surface SF3 of the base layer BSL. However, the invention is not necessarily limited thereto.

In an embodiment, the coating layer CTL may be formed to cover the light blocking member BM. That is, the coating layer CTL may be formed to contact the light blocking member BM.

In an embodiment, the coating layer CTL may include or be formed of an organic material. In an embodiment, for example, the coating layer CTL may include or be formed of an epoxy-based resin, an acrylic-based resin, an imide-based resin, or the like.

In an embodiment, the coating layer CTL may be formed in various ways. In an embodiment, for example, the coating layer CTL may be formed by at least one process selected from inkjet printing, roll laminating, spray coating, spin coating, roll coating, slot coating, dip coating, bar coating, gravure coating, micro gravure coating, and wire coating. However, a process of forming the coating layer CTL is not limited thereto.

In an embodiment, the coating layer CTL may be formed to have the second thickness T2 in a range of about 10 μm to about 50 μm. In an embodiment, for example, the coating layer CTL may be formed to have the second thickness T2 in a range of about 30 μm to about 50 μm.

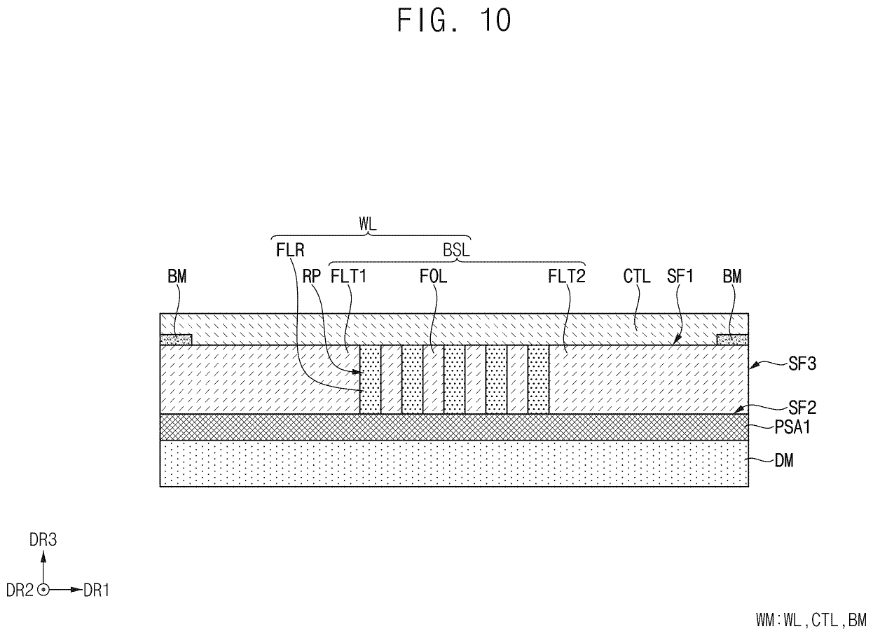

Referring further to FIG. 10, the window module WM and the display module DM may be bonded to each other. In an embodiment, for example, the window module WM may be adhered to the display module DM by the first adhesive layer PSA1. That is, the carrier film CF may be removed before bonding the window module WM and the display module DM, and the display module DM may be adhered on one surface of the first adhesive layer PSA1 from which the carrier film CF is removed. Accordingly, the window module WM and the display module DM may be bonded to each other by the first adhesive layer PSA1.

In an embodiment, as shown in FIG. 2, the protective film PFL, the buffer member CM, and the support module SM may be bonded under the display module DM by a plurality of adhesive layers. Accordingly, the display device DD including the support module SM, the buffer member CM, the protective film PFL, the display module DM, the window module WM, and the adhesive layers PSA1, PSA2, PSA3, PSA4-1, and PAS4-2 may be formed.

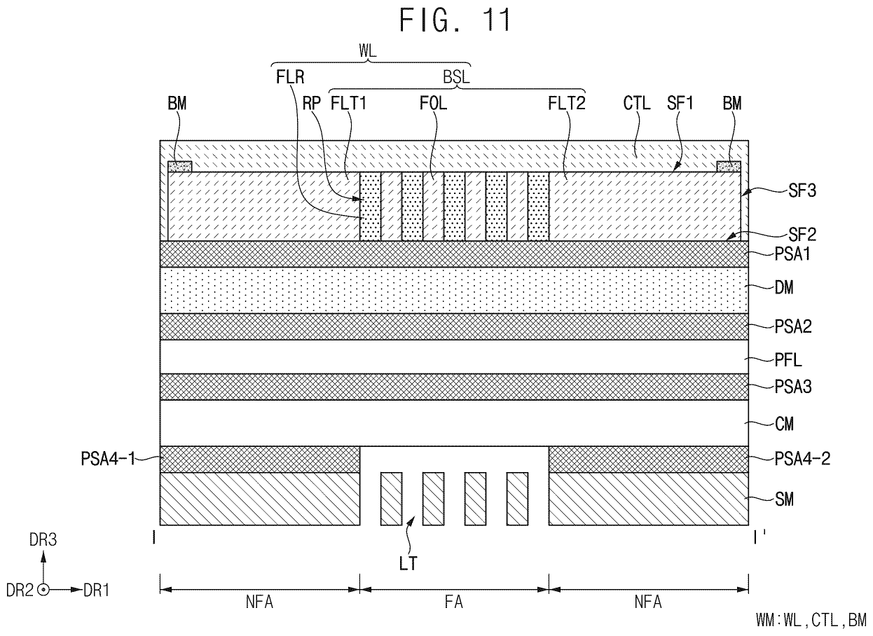

FIG. 11 is a cross-sectional view taken along line I-T of FIG. 1 illustrating an alternative embodiment.

Referring to FIG. 11, in an alternative embodiment, the coating layer CTL may cover the third surface SF3 of the base layer BSL. That is, the coating layer CTL may cover the first and third surfaces SF1 and SF3 of the base layer BSL. In such an embodiment, the coating layer CTL may cover the side surface of the window layer WL. Accordingly, an impact resistance of the window layer WL may be further improved.

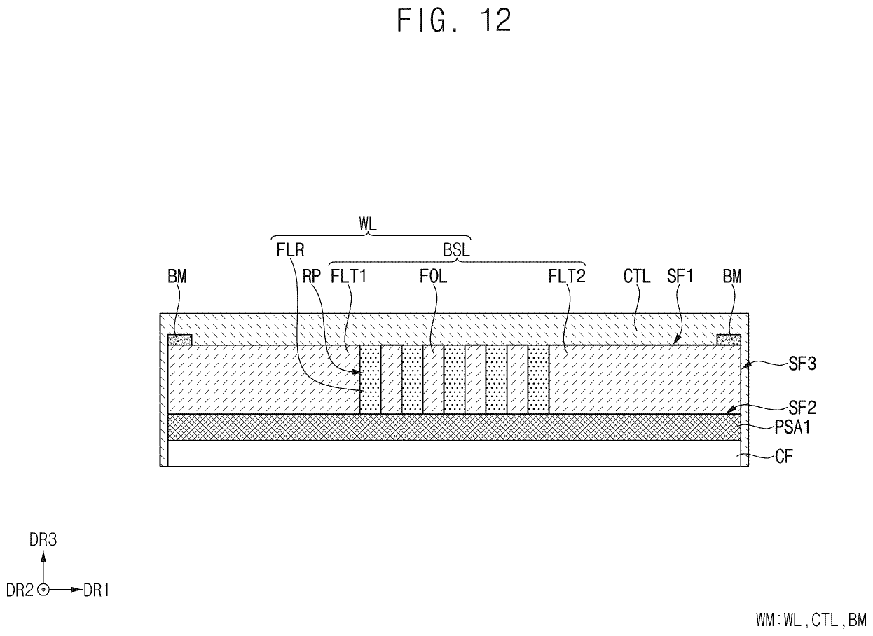

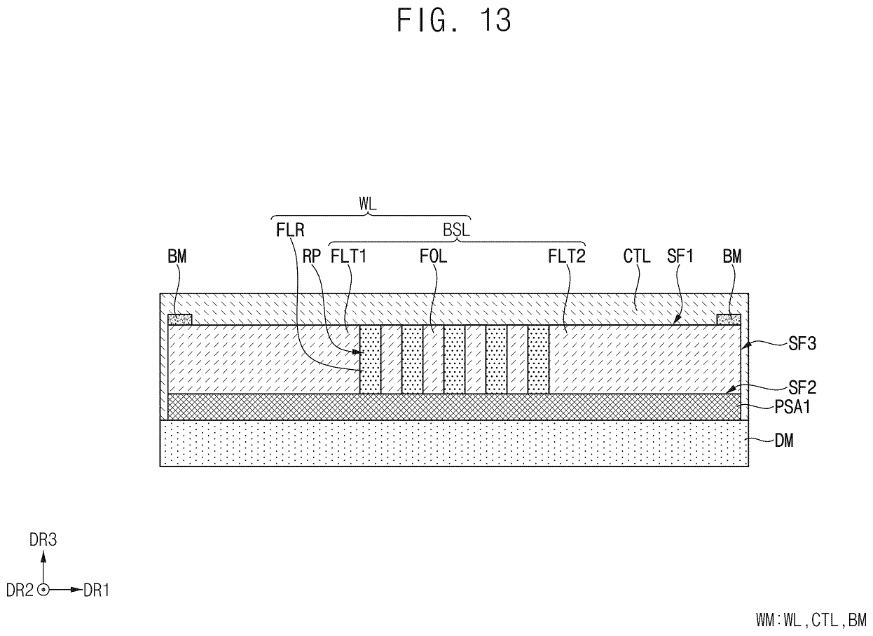

FIGS. 12 and 13 are cross-sectional views illustrating an embodiment of a manufacturing method of the display device of FIG. 11.

Hereinafter, an embodiment of a manufacturing method of the display device DD of FIG. 11 will be described with further reference to FIGS. 12 and 13.

First, as described with reference to FIGS. 4 to 8, the window layer WL, the light blocking member BM disposed on the upper surface of the window layer WL, and the first adhesive layer PSA1 disposed on the lower surface of the window layer WL may be formed.

Then, referring to FIG. 12, the coating layer CTL may be formed to cover the first and third surfaces SF1 and SF3 of the base layer BSL. In such an embodiment, the coating layer CTL may be formed to cover both the upper and side surfaces of the window layer WL.

Further referring to FIG. 13, before bonding the window module WM and the display module DM, the carrier film CF may be removed, and the display module DM may be adhered on one surface of the first adhesive layer PSA1 from which the carrier film CF is removed. Accordingly, the window module WM and the display module DM may be bonded by the first adhesive layer PSA1.

Then, as shown in FIG. 11, the protective film PFL, the buffer member CM, and the support module SM may be bonded under the display module DM by a plurality of adhesive layers. Accordingly, the display device DD including the support module SM, the buffer member CM, the protective film PFL, the display module DM, the window module WM, and the adhesive layers PSA1, PSA2, PSA3, PSA4-1, and PAS4-2 may be formed.

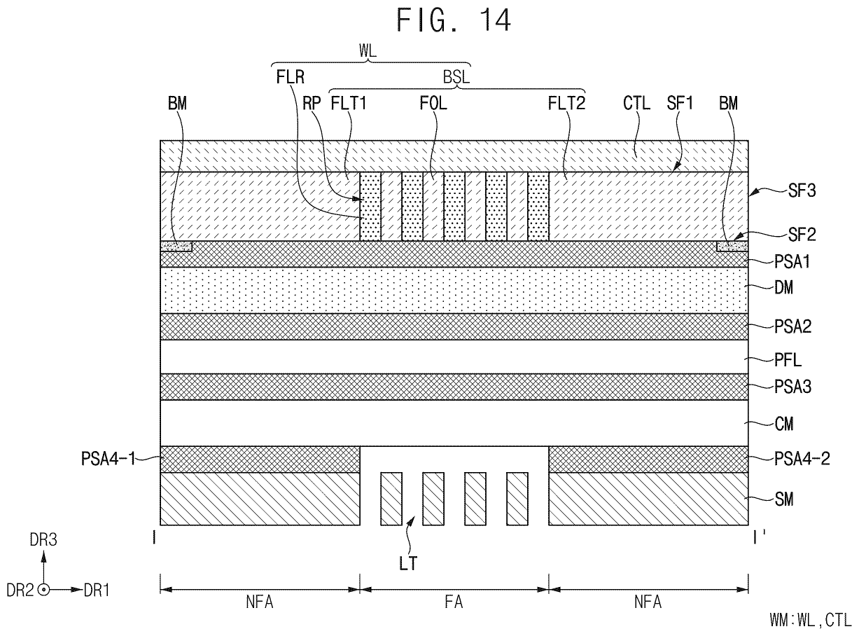

FIG. 14 is a cross-sectional view taken along line I-I of FIG. 1 illustrating an alternative embodiment.

Referring to FIG. 14, in an alternative embodiment, the light blocking member BM may be disposed between the display module DM and the window module WM. In such an embodiment, the window module WM may not include the light blocking member BM, and the light blocking member BM may be disposed under the window module WM. In such an embodiment, the first adhesive layer PSA1 may cover the light blocking member BM. In an embodiment, for example, the first adhesive layer PSA1 may contact the light blocking member BM.

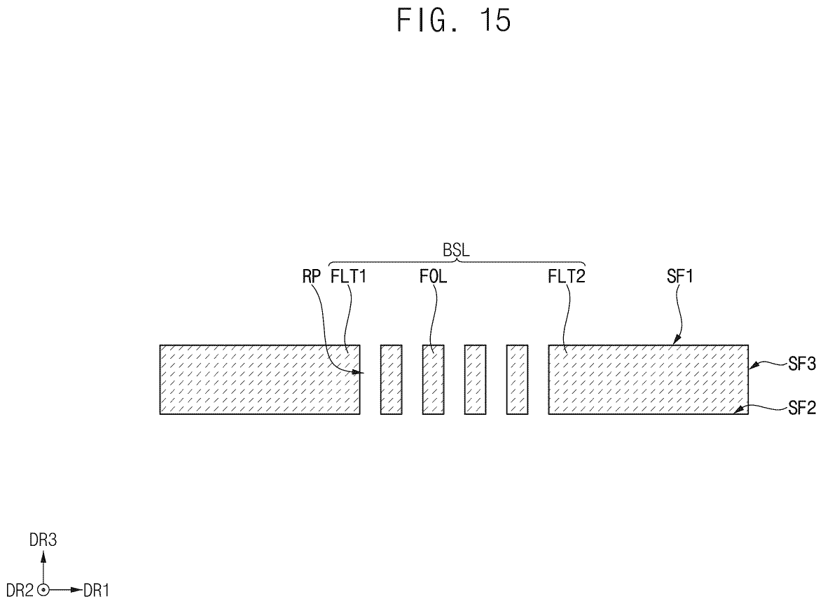

FIGS. 15 to 17 are cross-sectional views illustrating an embodiment of a manufacturing method of the display device of FIG. 14.

Hereinafter, an embodiment of a manufacturing method of the display device DD of FIG. 14 will be described with further reference to FIGS. 15 to 17.

First, referring to FIG. 15, the base layer BSL in which the recess pattern RP is defined may be formed. A process of forming the base layer BSL in which the recess pattern RP is defined may be substantially the same as the process described with reference to FIGS. 4 and 5.

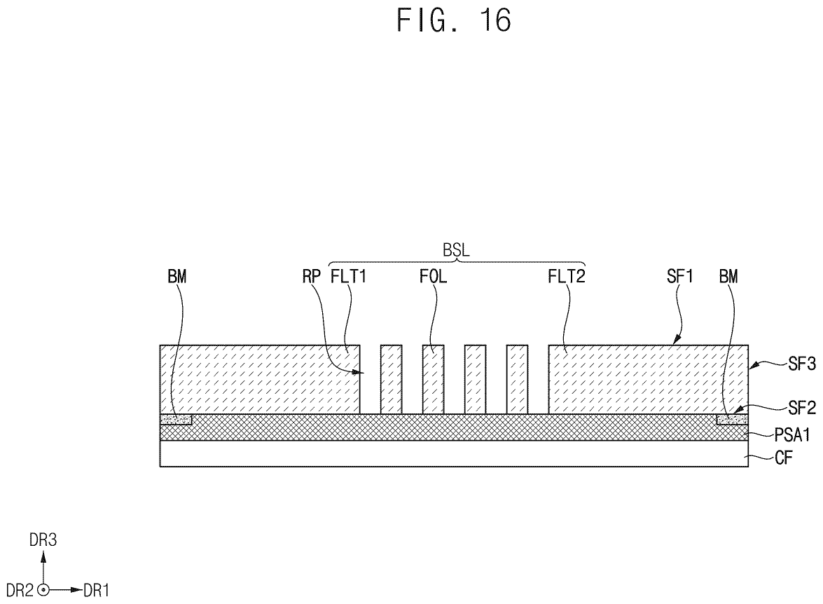

Then, referring to FIG. 16, the light blocking member BM and the first adhesive layer PSA1 may be formed on the second surface SF2 of the base layer BSL. In such an embodiment, the light blocking member BM may be formed on the second surface SF2 of the base layer BSL, and the first adhesive layer PSA1 may be formed to cover the light blocking member BM. That is, the first adhesive layer PSA1 may be formed to contact the light blocking member BM. In such an embodiment, the carrier film CF may be positioned under the first adhesive layer PSA1. As the first adhesive layer PSA1 is formed on the second surface SF2 of the base layer BSL, an accommodation space may be defined in the folding portion FOL.

In an embodiment, the light blocking member BM may be formed along the outer edge of the base layer BSL. That is, the light blocking member BM may be formed in a closed loop shape in a plan view.

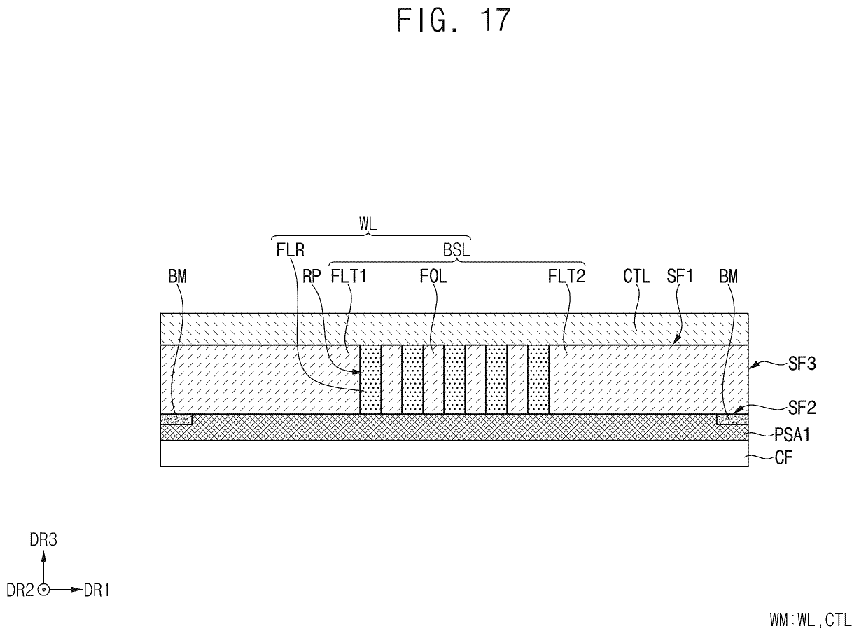

Then, referring to FIG. 17, the filler FLR may be filled in the recess pattern RP of the base layer BSL, and the coating layer CTL may be formed on the first surface SF1 of the base layer BSL. Accordingly, the window module WM including the window layer WL and the coating layer CTL may be formed. A process of filling the filler FLR may be substantially the same as the process described with reference to FIG. 7, and a process of forming the coating layer CTL may be substantially the same as the process described with reference to FIG. 9.

Then, the window module WM and the display module DM may be bonded to each other. A process of bonding the window module WM and the display module DM may be substantially the same as the process described with reference to FIG. 10. That is, the carrier film CF may be removed, and the display module DM may be adhered to one surface of the first adhesive layer PSA1 from which the carrier film CF is removed.

Then, as shown in FIG. 14, the protective film PFL, the buffer member CM, and the support module SM may be bonded under the display module DM by a plurality of adhesive layers. Accordingly, the display device DD including the support module SM, the buffer member CM, the protective film PFL, the display module DM, the window module WM, and the adhesive layers PSA1, PSA2, PSA3, PSA4-1, and PAS4-2 may be formed.

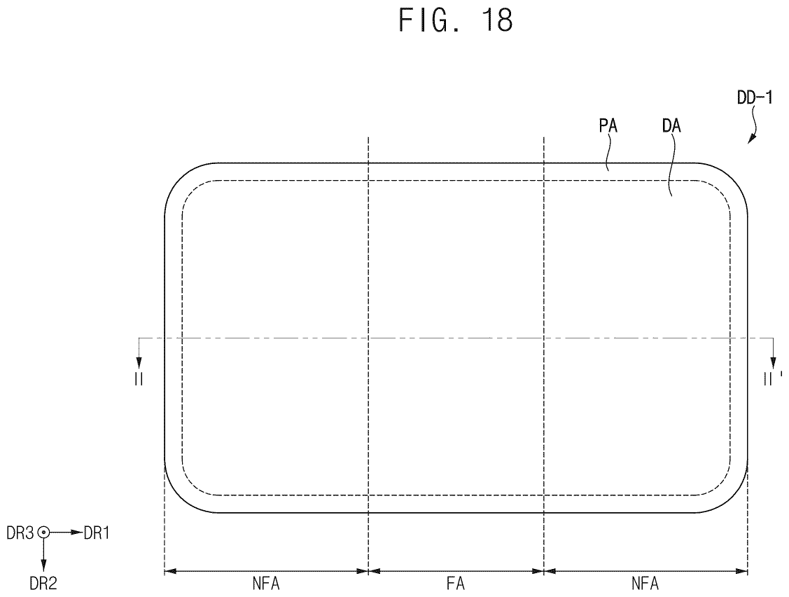

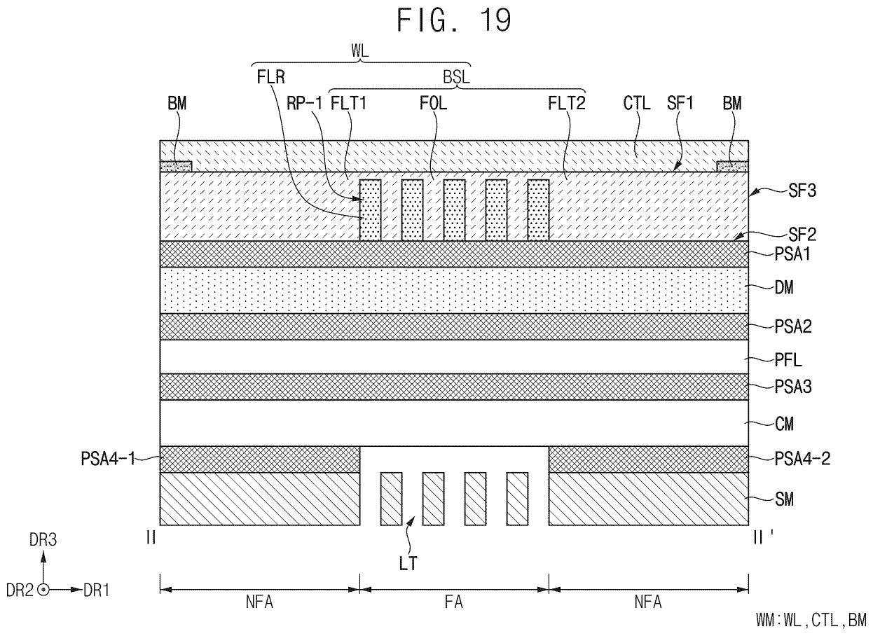

FIG. 18 is a plan view illustrating a display device according to an embodiment, and FIG. 19 is a cross-sectional view taken along line II-II of FIG. 18 illustrating an embodiment.

Particularly, FIG. 18 may correspond to a plan view of FIG. 1 and FIG. 19 may correspond to a cross-sectional view of FIG. 2.

Referring to FIGS. 18 and 19, a display device DD-1 according to an embodiment may be substantially the same as the display device DD described with reference to FIGS. 1 and 2 except for a recess pattern RP-1. Therefore, any repetitive detailed descriptions of the same or like elements as those described above will be omitted.

In an embodiment, the recess pattern RP-1 may be defined in the folding portion FOL, and the recess pattern RP-1 may be a trench pattern that is depressed into the base layer BSL from the second surface SF2 of the base layer BSL. That is, the recess pattern RP-1 may extend from the second surface SF2 of the base layer BSL to inside of the base layer BSL, but does not extend to the first surface SF1 of the base layer BSL.

In an embodiment, the filler FLR may be filled in the recess pattern RP-1. The filler FLR may include a soft material. In an embodiment, for example, the filler FLR may be a resin. In an embodiment, for example, the filler FLR may be a resin having a same refractive index as a refractive index of the base layer BSL. Accordingly, refractive indices of the base layer BSL and the filler FLR may be substantially the same as each other.

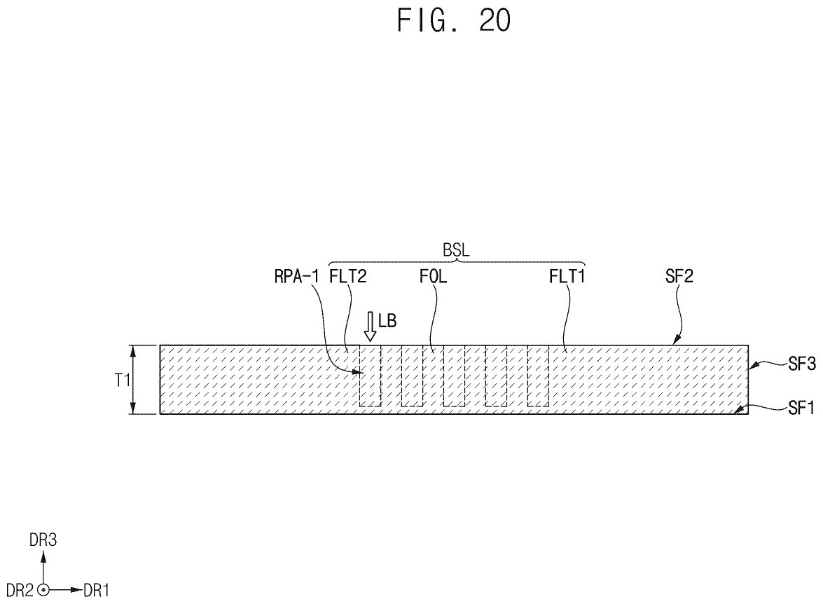

FIGS. 20 to 26 are cross-sectional views illustrating an embodiment of a manufacturing method of the display device of FIG. 19.

An embodiment of the display device DD-1 may include the window module WM and the display module DM, and an embodiment of a manufacturing method of the display device DD-1 may include forming the display module DM, forming the window module WM, and bonding the display module DM and the window module WM. Hereinafter, a process of forming the window module WM of FIG. 19 and a process of bonding the window module WM and display module DM of FIG. 19 will be described in detail with reference to FIGS. 20 to 26.

Referring to FIG. 20, the base layer BSL may be prepared. The base layer BSL may include the first surface SF1, the second surface SF2, and the third surface SF3. The first surface SF1 and the second surface SF2 may be opposite to each other. The third surface SF3 may connect the first surface SF1 and the second surface SF2 and may be a side surface of the base layer BSL.

In an embodiment, the base layer BSL may have the first thickness T1 in a range of about 100 μm to about 200 μm. In an embodiment, for example, the base layer BSL may have the first thickness T1 in a range of about 100 μm to about 150 μm.

A laser LB may be radiated to a recess pattern area RPA-1 of the base layer BSL. In an embodiment, the recess pattern area RPA-1 may be an area where the recess pattern RP-1 is formed. The laser LB may travel in the first direction DR1 and may be radiated to the first surface SF1. In such an embodiment, the laser LB may be selectively radiated to a portion of the first surface SF1 corresponding to the recess pattern area RPA-1. As the laser LB is radiated onto the recess pattern area RPA-1, the recess pattern area RPA-1 may have a different etching selectivity than an area not irradiated with the laser LB.

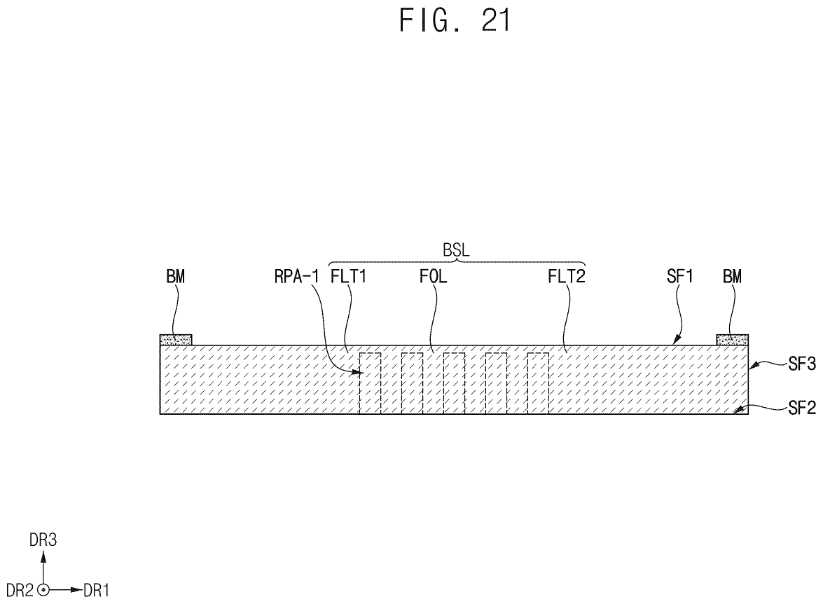

Further referring to FIG. 21, the light blocking member BM may be formed on the first surface SF1 of the base layer BSL. The light blocking member BM may be formed along the outer edge of the base layer BSL. That is, the light blocking member BM may be formed in a closed loop shape in a plan view.

The light blocking member BM may be formed in various ways. In an embodiment, the light blocking member BM may be formed through an inkjet printing process. In an alternative embodiment, the light blocking member BM may be formed through a screen-printing process. However, a process of forming the light blocking member BM is not limited thereto.

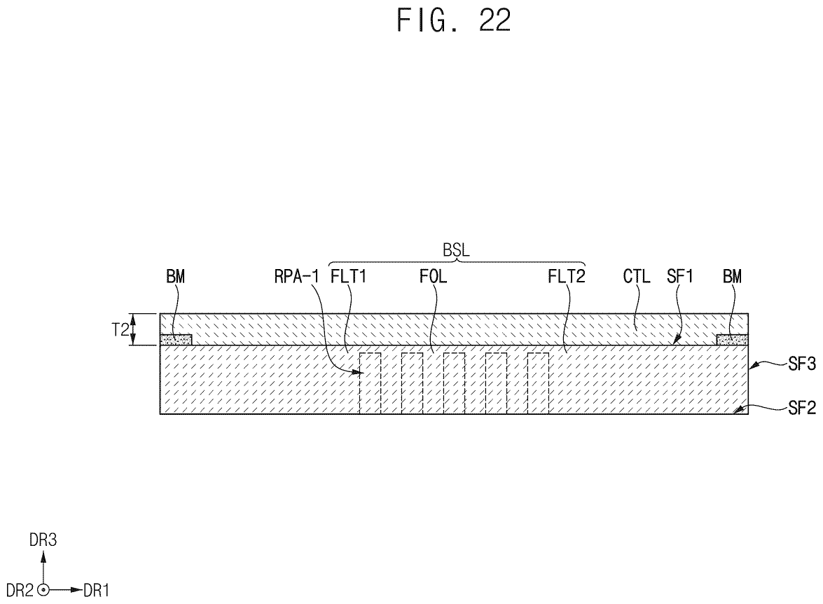

Further referring to FIG. 22, the coating layer CTL may be formed on the first surface SF1 of the base layer BSL.

The coating layer CTL may be directly formed on the first surface SF1 of the base layer BSL. That is, the coating layer CTL may be formed to contact the first surface SF1 of the base layer BSL. In an embodiment, for example, the coating layer CTL may be formed to cover the first surface SF1 of the base layer BSL. In such an embodiment, the coating layer CTL may be formed to cover the upper surface of the window layer WL. In an embodiment, the coating layer CTL may be formed to expose the third surface SF3 of the base layer BSL. However, the invention is not necessarily limited thereto.

In an embodiment, the coating layer CTL may be formed to cover the light blocking member BM. That is, the coating layer CTL may be formed to contact the light blocking member BM.

In an embodiment, the coating layer CTL may include or be formed of an organic material. In an embodiment, for example, the coating layer CTL may be formed of an epoxy-based resin, an acrylic-based resin, an imide-based resin, or the like.

In an embodiment, the coating layer CTL may be formed in various ways. In an embodiment, for example, the coating layer CTL may be formed by at least one process selected from inkjet printing, roll laminating, spray coating, spin coating, roll coating, slot coating, dip coating, bar coating, gravure coating, micro gravure coating, and wire coating. However, a process of forming the coating layer CTL is not limited thereto.

In an embodiment, the coating layer CTL may be formed to have the second thickness T2 in a range of about 10 μm to about 50 μm. Preferably, the coating layer CTL may be formed to have the second thickness T2 in a range of about 30 μm to about 50 μm.

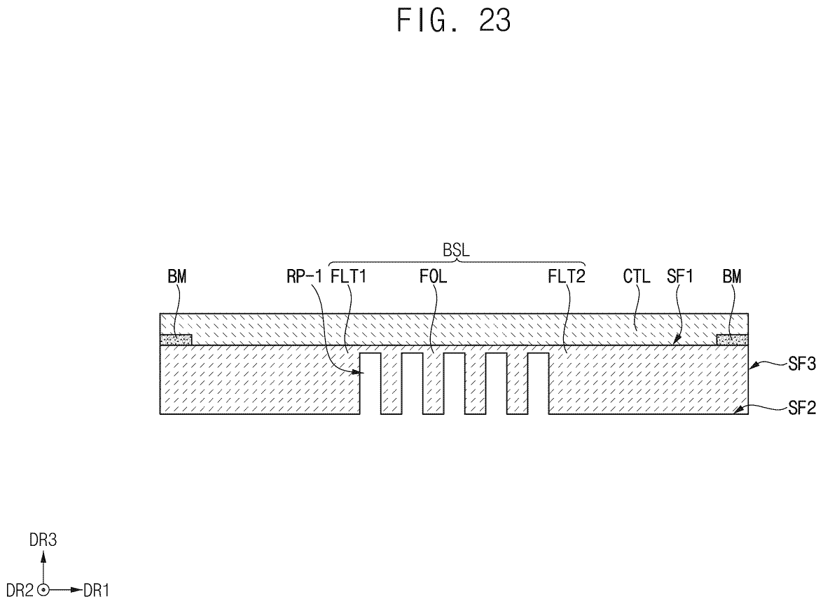

Further referring to FIG. 23, the base layer BSL may be etched in a way such that the recess pattern RP-1 may be formed. That is, the base layer BSL may react with an etchant. In such an embodiment, various processes for bringing the base layer BSL into contact with the etchant may be used. In an embodiment, for example, the base layer BSL may be immersed in the etchant or the etchant may be sprayed on the base layer BSL.

As described above, the recess pattern area RPA-1 may have a different etching selectivity than the area not irradiated with the laser LB. Accordingly, the recess pattern area RPA-1 may react with the etchant, and the base layer BSL corresponding to the recess pattern area RPA-1 may be etched. Thus, the recess pattern RP-1 may be formed. In an embodiment, the recess pattern RP-1 may be a trench pattern depressed into the base layer BSL from the second surface SF2 of the base layer. As the recess pattern RP-1 is formed in the base layer BSL, an accommodation space may be defined in the folding portion FOL.

In an embodiment, the coating layer CTL may not react with the etchant. Therefore, the coating layer CTL may not be removed or damaged while the base layer BSL is being etched.

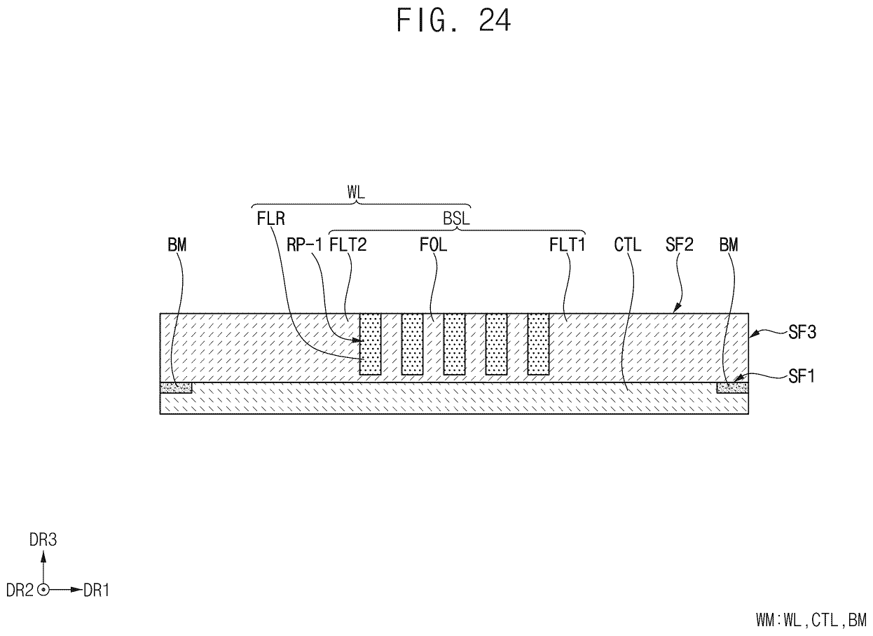

Further referring to FIG. 24, the filler FLR may be filled in the recess pattern RP-1. That is, the filler FLR may be filled in the accommodation space. Accordingly, the window layer WL including the base layer BSL and the filler FLR may be formed. Also, the window module WM including the window layer WL, the coating layer CTL, and the light blocking member BM may be formed.

As described above, the base layer BSL may have the first thickness T1 in a range of about 100 μm to about 200 μm. In an embodiment for example, the base layer BSL may have the first thickness T1 in a range of about 100 μm to about 150 μm. Accordingly, the window layer WL may be formed to have the first thickness T1 in a range of about 100 μm to about 200 μm, e.g., in a range of about 100 μm to about 150 μm.

The filler FLR may be filled in various ways. In an embodiment, the filler FLR may be filled through an inkjet process. In an alternative embodiment, the filler FLR may be filled through a spray coating process. In an alternative embodiment, the filler FLR may be filled through a roll laminating process. However, a process of filling the filler FLR is not limited thereto.

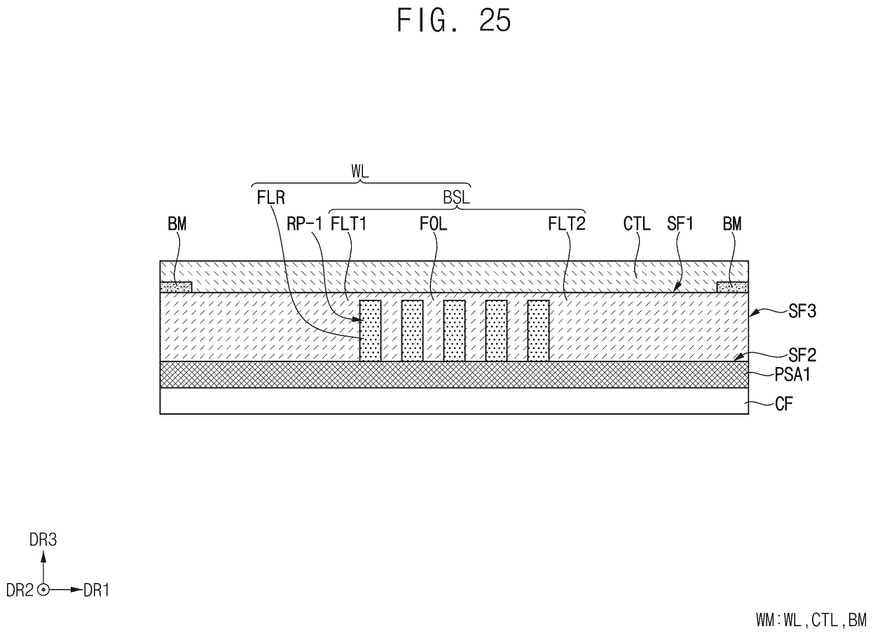

Further referring to FIG. 25, the first adhesive layer PSA1 may be formed on the second surface SF2 of the base layer BSL. In this case, the carrier film CF may be positioned under the first adhesive layer PSA1.

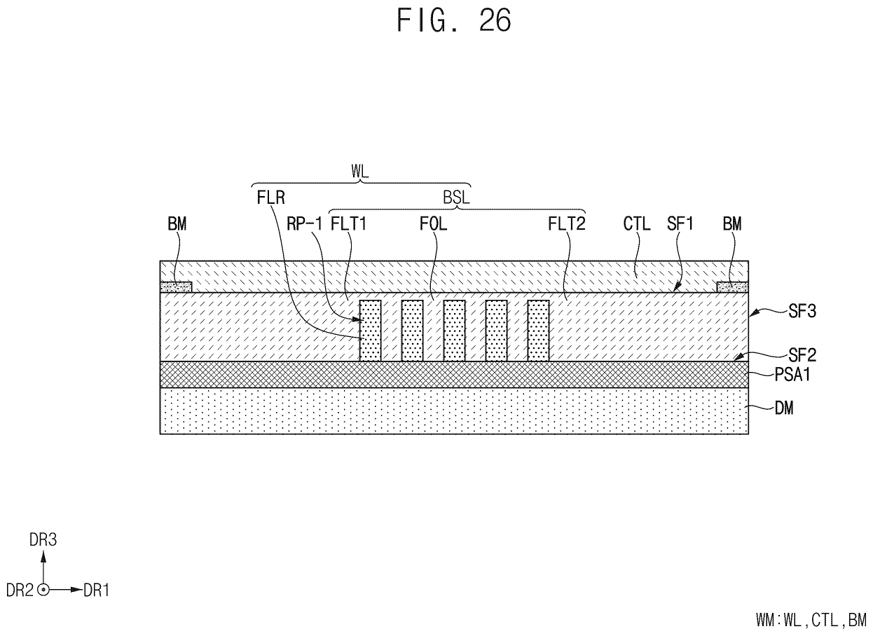

Referring further to FIG. 26, the window module WM and the display module DM may be bonded to each other. In an embodiment, for example, the window module WM may be adhered to the display module DM by the first adhesive layer PSA1. That is, the carrier film CF may be removed before bonding the window module WM and the display module DM, and the display module DM may be adhered on one surface of the first adhesive layer PSA1 from which the carrier film CF is removed. Accordingly, the window module WM and the display module DM may be bonded by the first adhesive layer PSA1.

In an embodiment, as shown in FIG. 19, the protective film PFL, the buffer member CM, and the support module SM may be bonded under the display module DM by a plurality of adhesive layers. Accordingly, the display device DD-1 including the support module SM, the buffer member CM, the protective film PFL, the display module DM, the window module WM, and the adhesive layers PSA1, PSA2, PSA3, PSA4-1, and PAS4-2 may be formed.

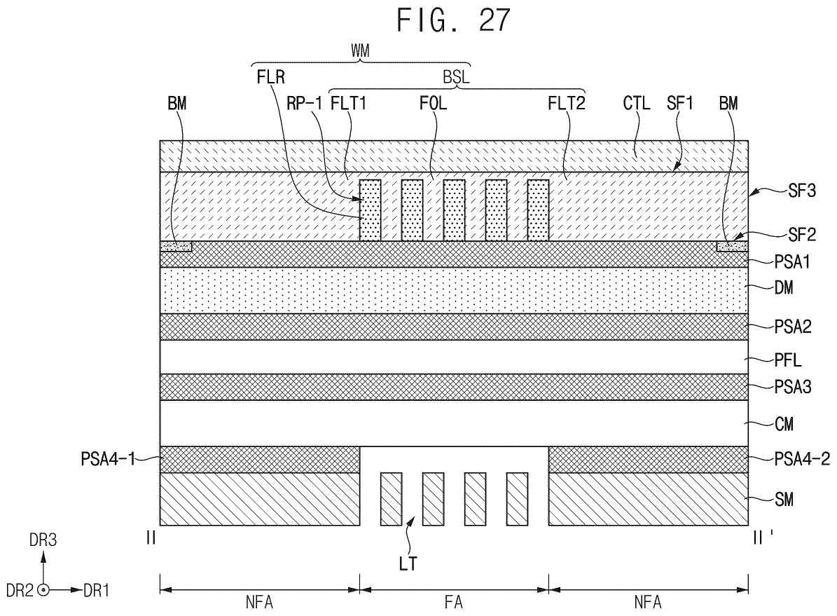

FIG. 27 is a cross-sectional view taken along line II-II of FIG. 18 according to an alternative embodiment. Particularly, FIG. 27 may correspond to a cross-sectional view of FIG. 19.

Referring to FIG. 27, in an embodiment, where the recess pattern RP-1, which is a trench pattern, is defined in the base layer BSL, the light blocking member BM may be disposed between the display module DM and the window module WM. That is, the window module WM may not include the light blocking member BM, and the light blocking member BM may be disposed under the window module WM. In such an embodiment, the first adhesive layer PSA1 may cover the light blocking member BM. In an embodiment, for example, the first adhesive layer PSA1 may contact the light blocking member BM.

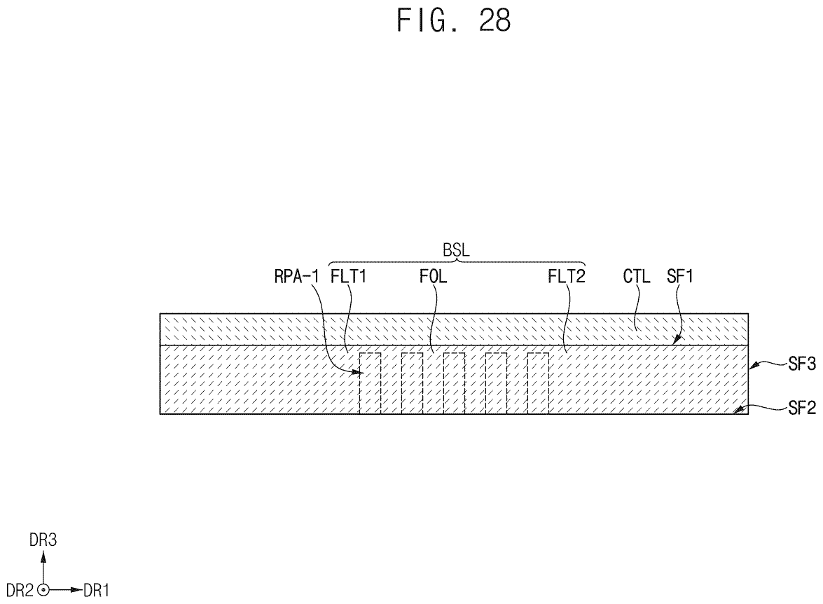

FIGS. 28 to 30 are cross-sectional views illustrating an embodiment of a manufacturing method of the display device of FIG. 27.

Hereinafter, an embodiment of a manufacturing method of the display device DD-1 of FIG. 27 will be described with further reference to FIGS. 28 to 30.

First, referring to FIG. 28, the base layer BSL to which laser is selectively radiated in the recess pattern area RPA-1 may be formed, and the coating layer CTL may be formed on the first surface SF1 of the base layer BSL. A process of forming the base layer BSL to which the laser is selectively radiated in the recess pattern area RPA-1 may be substantially the same as the process described with reference to FIG. 20, a process forming the coating layer CTL on the first surface SF1 of the base layer BSL may be substantially the same as the process described with reference to FIG. 22. However, as shown in FIG. 28, the light blocking member may not be formed on the first surface SF1 of the base layer BSL before forming the coating layer CTL.

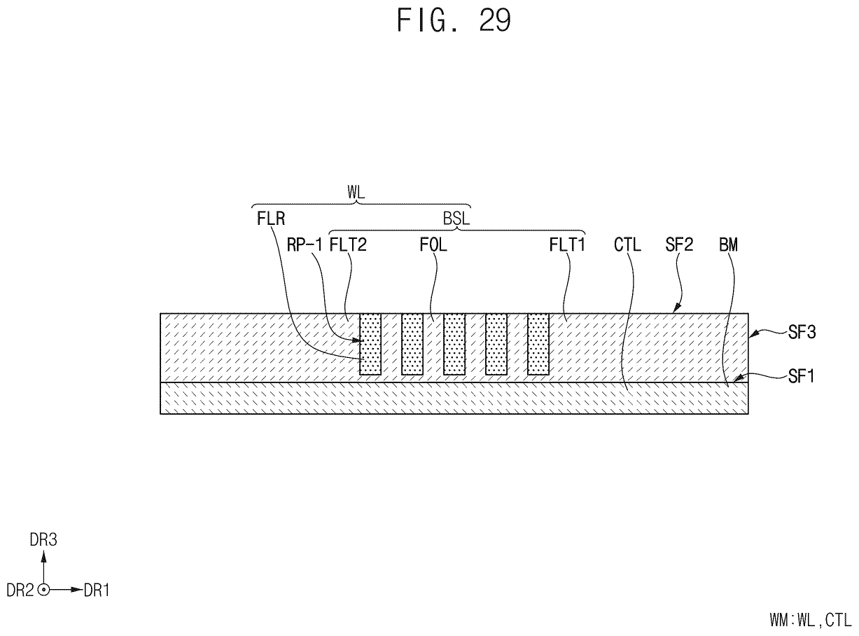

Then, referring to FIG. 29, the recess pattern RP-1 may be formed, and the filler FLR may be filled in the recess pattern RP-1. Accordingly, the window layer WL including the base layer BSL and the filler FLR may be formed. Also, the window module WM including the window layer WL and the coating layer CTL may be formed. A process of forming the recess pattern RP-1 and filling the filler FLR in the recess pattern RP-1 may be substantially the same as the process described with reference to FIGS. 23 and 24.

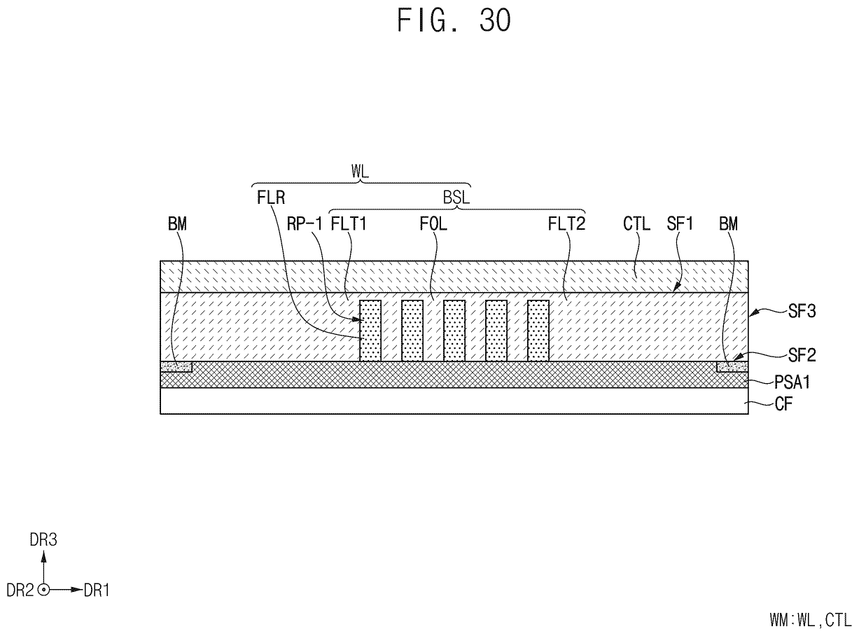

Then, referring to FIG. 30, the light blocking member BM and the first adhesive layer PSA1 may be formed on the second surface SF2 of the base layer BSL. That is, the light blocking member BM may be formed on the second surface SF2 of the base layer BSL, and the first adhesive layer PSA1 may be formed to cover the light blocking member BM. That is, the first adhesive layer PSA1 may be formed to contact the light blocking member BM. In such an embodiment, the carrier film CF may be positioned under the first adhesive layer PSA1.

in an embodiment, the light blocking member BM may be formed along the outer edge of the base layer BSL. That is, the light blocking member BM may be formed in a closed loop shape in a plan view.

Then, the window module WM and the display module DM may be bonded to each other. A process of bonding the window module WM and the display module DM may be substantially the same as the process described with reference to FIG. 26. That is, the carrier film CF may be removed, and the display module DM may be adhered to one surface of the first adhesive layer PSA1 from which the carrier film CF is removed.

Then, as shown in FIG. 27, the protective film PFL, the buffer member CM, and the support module SM may be bonded under the display module DM by a plurality of adhesive layers. Accordingly, the display device DD-1 including the support module SM, the buffer member CM, the protective film PFL, the display module DM, the window module WM, and the adhesive layers PSA1, PSA2, PSA3, PSA4-1, and PAS4-2 may be formed.

According to embodiments, the display device may include the display module DM and the window module WM disposed on the display module DM and capable of being folded or foldable. In such embodiments, the window module WM may include the window layer WL and the coating layer CTL disposed on the window layer WL. In such embodiments, the window layer WL may include the base layer BSL and the filler FLR filled in the recess pattern defined in the base layer BSL, and the coating layer CTL may contact the upper surface of the base layer BSL. In such embodiments, the coating layer CTL may be directly formed on or disposed directly on the upper surface of the base layer BSL.

As the window module WM includes the coating layer CTL contacting the upper surface of the base layer BSL, the window layer WL included in the window module WM may have a low modulus and may be smoothly folded. In an embodiment, for example, as the window module WM includes the coating layer CTL, the window layer WL included in the window module WM may have a modulus of about 100 Mpa or less. Accordingly, the window module WM may be smoothly folded, and a durability of the window module WM may be improved. Accordingly, structural reliability of the display device may be improved.

The invention should not be construed as being limited to the embodiments set forth herein. Rather, these embodiments are provided so that this disclosure will be thorough and complete and will fully convey the concept of the invention to those skilled in the art. While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display module which displays an image; and
a window module disposed on the display module, wherein the window module is foldable, and
wherein the window module includes:
a window layer including a base layer with a recess pattern and a filler filled in the recess pattern; and
a coating layer disposed on the window layer and contacting an upper surface of the base layer.

2. The display device of claim 1, wherein a modulus of the coating layer is in a range of about 2 times to about 20 times a modulus of the window layer.

3. The display device of claim 2, wherein
the modulus of the window layer is in a range of about 5 Mpa to about 100 Mpa, and
the modulus of the coating layer is in a range of about 10 Mpa to about 2000 Mpa.

4. The display device of claim 2, wherein
a thickness of the window layer is in a range of about 100 μm to about 200 μm, and
a thickness of the coating layer is in a range of about 10 μm to about 50 μm.

5. The display device of claim 1, wherein the recess pattern is an opening pattern defined through the base layer.

6. The display device of claim 1, wherein the recess pattern is a trench pattern which is depressed into the base layer from a lower surface opposite to the upper surface of the base layer.

7. The display device of claim 1, wherein the window module further includes a light blocking member disposed on the base layer, and
the coating layer contacts the light blocking member and covers the light blocking member.

8. The display device of claim 1, further comprising:
a light blocking member disposed between the display module and the window module, and
an adhesive layer disposed between the display module and the window module and contacting the light blocking member.

9. The display device of claim 1, wherein the coating layer covers the upper surface of the base layer.

10. The display device of claim 9, wherein the coating layer covers the upper surface of the base layer and a side surface of the base layer.

11. A method of manufacturing a display device, the method comprising:
forming a display module which displays an image;
forming a window module; and
bonding the display module and the window module to each other, and
the forming the window module includes:
radiating a laser to a base layer;
forming an opening pattern through the base layer by etching the base layer by reacting an etchant with an area irradiated with the laser;
forming an adhesive layer on a lower surface of the base layer;
forming a window layer including the base layer and a filler by filling the opening pattern with the filler; and
forming a coating layer on an upper surface opposite to the lower surface of the base layer.

12. The method of claim 11, wherein the coating layer is formed by at least one process selected from inkjet printing, roll laminating, spray coating, spin coating, roll coating, slot coating, dip coating, bar coating, gravure coating, micro gravure coating, and wire coating.

13. The method of claim 11, wherein
the window layer has a thickness in a range of about 100 μm to about 200 μm,
the coating layer has a thickness in a range of about 10 μm to about 50 μm, and
a modulus of the coating layer is in a range of about 2 times to about 20 times a modulus of the window layer.

14. The method of claim 11, wherein the forming the window module includes forming a light blocking member on the base layer after the forming the window layer and before the forming the coating layer, and
the coating layer is formed to contact the light blocking member and cover the light blocking member.

15. The method of claim 11, wherein the forming the window module further includes forming a light blocking member under the base layer, and
the adhesive layer is formed to contact the light blocking member.

16. A method of manufacturing a display device, the method comprising:
forming a display module which displays an image;
forming a window module; and
bonding the display module and the window module to each other, and
the forming the window module includes:
radiating a laser to a base layer;
forming a coating layer on an upper surface of the base layer to contact the base layer;
forming a trench pattern which is depressed into the base layer from a lower surface opposite to the upper surface of the base layer by etching the base layer by reacting an etchant with an area irradiated with the laser;
forming a window layer including the base layer and a filler by filling the trench pattern with the filler; and
forming an adhesive layer on the lower surface of the base layer.

17. The method of claim 16, wherein the coating layer is formed by at least one process selected from inkjet printing, roll laminating, spray coating, spin coating, roll coating, slot coating, dip coating, bar coating, gravure coating, micro gravure coating, and wire coating.

18. The method of claim 16, wherein
the window layer has a thickness in a range of about 100 μm to about 200 μm,
the coating layer has a thickness in a range of about 10 μm to about 50 μm, and
a modulus of the coating layer is in a range of about 2 times to about 20 times a modulus of the window layer.

19. The method of claim 16, wherein
the forming the window module includes forming a light blocking member on the base layer before the forming the coating layer, and
the coating layer is formed to contact the light blocking member and cover the light blocking member.

20. The method of claim 16, wherein
the forming the window module includes forming a light blocking member on a lower surface of the window layer opposite to an upper surface of the window layer on which the coating layer is formed, and
the adhesive layer is formed to contact the light blocking member.
